(19) United States
(12) Patent Application Publication
(10) Pub. No.: US 2019/0054582 A1
(43) Pub. Date: Feb. 21, 2019

(54) PRESS-FIT DEVICE AND TOUCH PANEL SURFACE SENSOR DETECTION DEVICE

(71) Applicants: BOE TECHNOLOGY GROUP CO., LTD., Beijing (CN); HEFEI BOE OPTOELECTRONICS TECHNOLOGY CO., LTD., Anhui (CN)

(72) Inventors: Menglong SHE, Beijing (CN); Zhongshan WANG, Beijing (CN); Ming LI, Beijing (CN)

(73) Assignees: BOE TECHNOLOGY GROUP CO., LTD., Beijing (CN); HEFEI BOE OPTOELECTRONICS TECHNOLOGY CO., LTD., Anhui (CN)

(21) Appl. No.: 15/560,842

(22) PCT Filed: Mar. 16, 2017
(86) PCT No.: PCT/CN2017/076949

§ 371 Date: Sep. 22, 2017

(30) Foreign Application Priority Data
May 6, 2016 (CN) 201610298640.4

(51) Int. Cl. B23P 19/10; G06F 3/041; G06T 7/70; B23P 19/02; H05K 13/00; H05K 13/08

(52) U.S. Cl. CPC B23P 19/10; G06F 3/041; G06T 7/70; G06F 2203/04103; H05K 13/0015; H05K 13/0069; H05K 13/0882; B23P 19/02

(57) ABSTRACT

Disclosed are a press-fit device and a touch panel surface sensor detection device, the press-fit device is to press a first plate on a substrate. The press-fit device includes: a substrate stage for placing the substrate; a ram, arranged on the substrate stage and used to secure a printed circuit board; a ram movement member, connected with the ram and used to control the ram to be pressed down or raised up in a first direction perpendicular to the substrate stage; a controller, used to control an operating state of the ram movement member; and an alignment member, used to control alignment of the ram and the substrate stage and connected to the ram and the substrate stage.

### CROSS-REFERENCE TO RELATED APPLICATION

The present application claims a priority to Chinese Patent Application No. 201610298640.4 filed on May 6, 2016, the disclosure of which is incorporated in its entirety by reference herein.

### TECHNICAL FIELD

The present disclosure relates to the field of display technology, in particular to a press-fit device and a touch panel surface sensor detection device.

### BACKGROUND

In recent years, the display technology has developed rapidly, there are large differences between the flat panel displays and the traditional video image displays, since the flat panel displays employ a completely different display and manufacturing technology. The traditional video image displays are mainly cathode ray tubes; and the main difference between the traditional video image displays and the flat panel displays is the weight and the volume (thickness), specifically, the thickness of the flat panel displays is usually not more than 10 cm, further, there are other differences, such as a display principle, manufacturing materials, manufacturing process and techniques with respect to the video image display driver, and the like. The flat panel displays are completely flat, light, thin and power-saving, and it is an inevitable tendency that the flat panel displays are widely used. Especially, high PPI products are the mainstream during the development of the image displays. The touch panel technology is also rapidly developed, initially, an attached touch panel is developed, and then a protective glass integrated touch panel is developed, and a box integrated touch control panel is developed at present, the touch panel becomes lighter, thinner, more sensitive, however, the test requirements are also increased, the problems that a error rate is high, test time is long and the film is easy to be broken, are to be solved.

### SUMMARY

It is an object of the present disclosure to provide a press-fit device and a touch panel surface sensor detection device, thereby solving the following problems of the touch panel surface sensor detection device in the related art that: for an automatic alignment apparatus, the manufacturing costs are high, whereas for a manual alignment apparatus, the test efficiency is low, the error rate is high, and the panel is easy to be broken.

Following technical solutions are provided in the present disclosure.

It is provided a press-fit device for pressing a first plate on a substrate, where the press-fit device includes: a substrate stage for placing the substrate; a ram, arranged on the substrate stage and configured to secure the first plate; a ram movement member, connected with the ram and configured to control the ram to be pressed down or raised up in a first direction perpendicular to the substrate stage; a controller, configured to control an operating state of the ram movement member; and an alignment member, configured to control alignment of the ram and the substrate stage and connected to the ram and the substrate stage.

Further, the alignment member includes: a ram position adjusting member, configured to control the ram to be moved in a plane parallel to a carrier surface of the substrate stage to adjust a position of the first plate on the ram; a substrate stage position adjusting member, configured to control the substrate stage to be moved in a plane in which the carrier surface of the substrate stage is located, to adjust a position of the substrate on the substrate stage; and an alignment controlling member, configured to obtain current position information of the first plate on the ram and the substrate on the substrate stage, and control operating states of the ram position adjusting member and the substrate stage position adjusting member according to the current position information, to align the first plate with the substrate.

Further, the alignment controlling member includes: an image acquisition member, arranged on the substrate stage and configured to acquire image information of the first plate on the ram and the substrate on the substrate stage and obtain the current position information of the first plate on the ram and the substrate on the substrate stage; and a control member, configured to control the operating states of the ram position adjusting member and the substrate stage position adjusting member according to the image information acquired by the image acquisition member.

Further, the alignment controlling member further includes an image acquisition member moving component, which is configured to move the image acquisition member.

Further, the ram position adjusting member includes: a ram moving member, which is configured to translate the ram in a second direction parallel to the carrier surface of the substrate stage.

Further, the substrate stage position adjusting member includes: a first stage moving member, configured to translate the substrate stage by the substrate in the second direction parallel to the carrier surface of the substrate stage; a second stage moving member, configured to translate the substrate stage by the substrate in a third direction perpendicular to the first direction and the second direction; and a third stage moving member, configured to rotate the substrate stage in the plane in which the carrier surface of the substrate stage is located.

Further, the ram movement member includes: a three-piece rail cylinder, capable of defining the position of the ram in a three positions in the first direction respectively.

Further, the controller includes a gas pressure regulating valve, which is configured to regulate a cylinder pressure of the three-piece rail cylinder to control an operating state of the three-piece rail cylinder.

Further, a substrate positioning member for positioning the substrate is provided on the carrier surface of the substrate stage.

Further, the substrate positioning member includes: a first positioning baffle, which is configured to position the substrate in a second direction parallel to a carrier surface of the substrate stage; and a second positioning baffle, which is configured to position the substrate in a third direction perpendicular to the first direction and the second direction.

Further, the carrier surface of the substrate stage is inclined with respect to a horizontal plane.

Further, a vent hole for reducing a pressure between the substrate and a carrier surface of the substrate stage is provided in the carrier surface of the substrate stage.

Further, the press-fit device further includes: an ion pump, which is arranged on the substrate stage and configured to blow a surface of the substrate and perform a dust removal and de-electrostatic process on the surface of the substrate.

Further, the substrate stage has at least two substrate placement areas for placing the substrate, there are two rams, and one of the two rams is provided at each of the substrate placement areas.

It is provided a touch panel surface sensor detection device, which includes the press-fit device described above.

According to the present disclosure, the following beneficial effects can be achieved.

The press-fit device provided by the present disclosure can be applied to a touch panel surface sensor detection device, and an alignment member is provided, such that the alignment accuracy can be improved, the test efficiency is higher, and the test error rate is lower; and in an alternative solution of the press-fit device provided in the present disclosure, the three-piece rail cylinder is employed, such that the test error rate due to the difference of the pressure applied by a manual alignment apparatus is avoided, and the stability of the apparatus is improved, and the damage chance of the panel is reduced.

### BRIEF DESCRIPTION OF THE DRAWINGS

FIG. 1 is a schematic perspective view of a press-fit device according to embodiments of the present disclosure;

FIG. 2 is a schematic perspective view of the press-fit device from another angle according to embodiments of the present disclosure; and

FIG. 3 is a side view of a press-fit device according to embodiments of the present disclosure.

### DETAILED DESCRIPTION OF THE EMBODIMENTS

In order to make the objects, the technical solutions and the advantages of the present disclosure more apparent, the present disclosure will be described hereinafter in a clear and complete manner in conjunction with the drawings and embodiments. Obviously, the following embodiments are merely a part of, rather than all of, the embodiments of the present disclosure. Based on these embodiments described in the present disclosure, those skilled in the art may obtain the other embodiments, which also fall within the scope of the present disclosure.

In a related art, there are two touch test apparatus: an automatic alignment type apparatus and a manual alignment type apparatus.

The automatic alignment apparatus can perform accurate alignment and a higher accuracy test, however, manufacturing costs are higher, the automatic alignment apparatus is heavy, and a procedure for switching models is cumbersome. The manual alignment apparatus is cheaper, compact and convenient. In the related art, the manual alignment apparatus often includes a ram and a panel stage. The ram is used to arrange and fix a flexible printed circuit board, a touch panel is arranged on the panel stage, and the ram can be lifted up and down such that the flexible printed circuit board is pressed on the touch panel. For the manual alignment apparatus, the alignment accuracy is poor, since the alignment of the flexible circuit and the touch panel depends on the observation of an operator. Due to the poor alignment accuracy, a test result of a touch panel surface sensor is affected, and a test error rate is higher. Moreover, in the related art, a pressure applied on the touch panel by the ram of the manual alignment apparatus is unstable; therefore, the panel is easier to be scrapped.

In order to solve the following technical problems in the related art: the automatic alignment apparatus can perform a higher accuracy test, while the manufacturing costs are higher, whereas the manual alignment apparatus performs a lower accuracy test and the test error rate is higher, it is provided a press-fit device according to the present disclosure, which has a simple structure, provides a higher test accuracy and a lower test error rate.

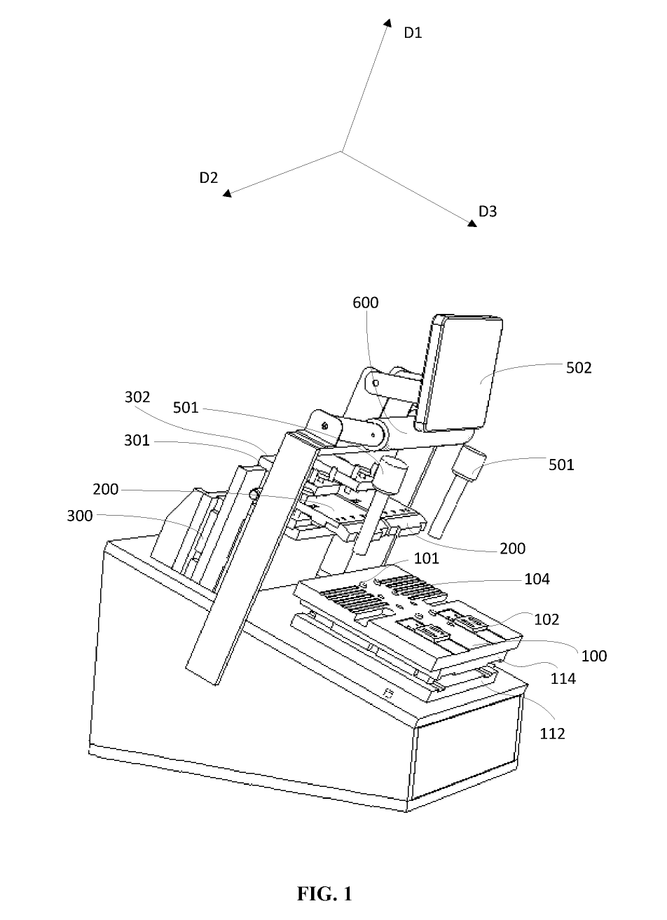

As shown in FIGS. 1-3, a press-fit device for pressing a first plate on a substrate is provided according to the present disclosure, where the press-fit device includes: a substrate stage 100 for placing the substrate; a ram 200, arranged on the substrate stage 100 and configured to secure the first plate; a ram movement member 300, connected with the ram 200 and configured to control the ram 200 to be pressed down or raised up in a first direction D1 perpendicular to the substrate stage 100; a controller, configured to control an operating state of the ram movement member 300; and an alignment member, configured to control alignment of the ram 200 and the substrate stage 100 and connected to the ram 200 and the substrate stage 100.

The press-fit device provided in the present disclosure can be applied to a touch panel surface sensor detection device, and the press-fit device is provided with the alignment member, thus, compared with the automatic alignment apparatus, the structure of the press-fit device is simpler and the manufacturing costs are lower, while compared with the manual alignment apparatus in the related art, the alignment accuracy is improved, and a test efficiency is higher, and the test error rate is lower. Specifically, when the press-fit device is applied to the detecting device for the touch panel surface sensor, the first plate is a flexible printed circuit board and the substrate is a touch panel.

Alternatively, in the press-fit device according to embodiments of the present disclosure, the alignment member includes: a ram position adjusting member 301, a substrate stage position adjusting member and an alignment controlling member, as shown in FIGS. 1-3.

Specifically, the ram position adjusting member 301 is configured to control the ram 200 to be moved in a plane parallel to a carrier surface of the substrate stage 100, to adjust a position of the first plate on the ram 200.

The substrate stage position adjusting member is configured to control the substrate stage 100 to be moved in a plane in which the carrier surface of the substrate stage 100 is located, to adjust a position of the substrate on the substrate stage 100.

The alignment controlling member is configured to obtain current position information of the first plate on the ram 200 and the substrate on the substrate stage 100, and control operating states of the ram position adjusting member 301 and the substrate stage position adjusting member according to the current position information, to align the first plate with the touch substrate.

With the above technical solution, before the first plate on the ram 100 is pressed on the substrate of the substrate stage 100, the alignment controlling member acquires the current position of the first plate and the substrate, and then controls the ram position adjusting member 301 and the substrate stage position adjusting member, and further adjusts the position of the ram 200 and the substrate stage 100, such that the first plate is pressed on the substrate by the ram 200 after the first plate is aligned with the substrate accurately, thereby improving the alignment accuracy of the first plate and the substrate, and reducing the test error rate.

Alternatively, in the press-fit device according to embodiments of the present disclosure, the alignment controlling member includes an image acquisition member 501 and a control member, as shown in FIGS. 1-3.

Specifically, the image acquisition member 501 is arranged on the substrate stage 100, which is configured to acquire image information of the first plate on the ram 200 and the substrate on the substrate stage 100 and obtain current position information of the first plate on the ram 200 and the substrate on the substrate stage 100.

The control member is configured to control operating states of the ram position adjusting member 301 and the substrate stage position adjusting member according to the image information acquired by the image acquisition member 501.

In the above technical solution, the image information of the first plate and the substrate can be obtained in an image acquisition manner, and then the position of the ram 200 and the substrate stage 100 is adjusted, and finally the first plate is aligned with the substrate.

Optionally, the alignment controlling member further includes an image acquisition member moving component, which configured to move the image acquisition member 501. With the above technical solution, the image acquisition member 501 is movable, such that images are continently acquired. Optionally, the image acquisition member moving component includes a slide rail, and the image acquisition member 501 is mounted on the slide rail, and is movable along the slide rail.

Specifically, according to embodiments of the present disclosure, as shown in FIGS. 1-3, the image acquisition member 501 can be a CCD camera, which is movably arranged on the substrate stage 100, and the CCD camera can clearly capture marking points located in left and right sides of the substrate on the substrate stage 100 and an alignment mark on the first plate on the ram 200, by adjusting a focal length and a position of the CCD camera. The control member includes a camera display 502 which can display an instant image captured by the CCD camera, and controls an operation state of the ram position adjusting member 301 and the substrate stage position adjusting member according to the displayed instant image, such that the first plate is aligned with the substrate.

It should be noted that, in the above solution, the alignment controlling member obtains the current position of the first plate on the ram 200 and the substrate on the substrate stage 100 by means of an image acquisition manner such as the CCD camera, however, in practical applications, the alignment controlling member may also obtain the current position of the first plate and the substrate in other manners, for example, by means of a position sensor or the like.

Further, it should be also noted that the image acquisition member 501 is not limited to the CCD camera, but may be another image acquisition component which can realize image acquisition, which is no longer enumerated here.

Additionally and optionally, in the press-fit device according to the embodiments of the present disclosure, the ram position adjusting member 301 includes a ram movement member 302, which is configured to translate the ram 200 in a second direction D2 parallel to the carrier surface of the substrate stage 100.

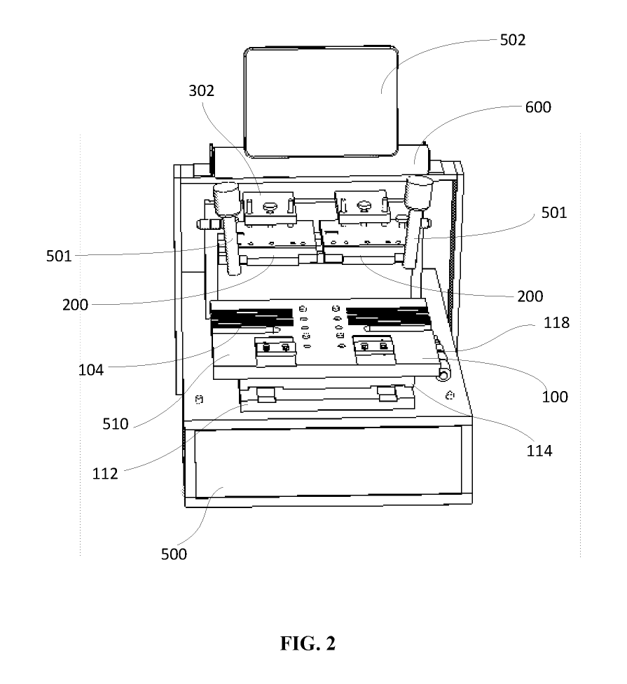

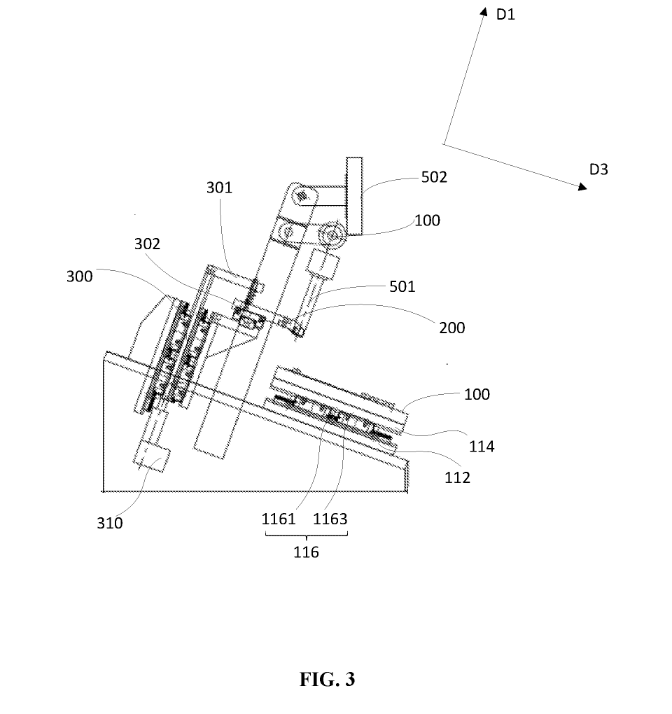

As shown in FIG. 2 and FIG. 3, the substrate stage position adjusting member includes a first stage movement member 112, a second stage movement member 114 and a third stage movement member 116.

The first stage moving member 112 is configured to translate the substrate stage 100 in the second direction D2 parallel to the carrier surface of the substrate stage 100.

The second stage movement member 114 is configured to translate the substrate stage 100 in a third direction D3 perpendicular to the first direction D1 and the second direction D2.

The third stage movement member 116 is configured to rotate the substrate stage 100 in the plane in which the carrier surface of the substrate stage 100 is located.

With the above technical solution, the ram 200 can be translated in the direction D2 parallel to the carrier surface of the substrate stage 100, such that a position of the ram 200 is adjusted, and a position of the first plate on the ram 200 is therefore adjusted, and the substrate plate 100 can be moved in the second direction D2 and the third direction D3 and can be rotated the plane in which the carrier surface of the substrate stage 100 is located such that the first plate is aligned with the substrate. In the above technical solution, optionally, the first stage movement member 112, the second stage movement member 114 and the third stage movement member 116 may use an adjustment micrometer 118 to precisely adjust the substrate stage 100.

In an embodiment, the first stage movement member 112 is arranged on an upper surface 510 of the stent 500 of the touch panel surface sensor detection device and is slidable relative to the upper surface 510 of the stent 500 in the second direction D2. The second stage movement member 114 is arranged on the first stage movement member 114, and is slidable relative to the upper surface 510 of the stent 500 in the second direction D2 together with the first stage movement member 112. Further, the second stage movement member 114 is slidable relative to the first stage movement member 112 in the third direction D3. The third stage moving member 116 includes a carrier plate 1163, which is rotatably mounted on the second stage movement member 114 through a rotation shaft 1161. The carrier plate 1163 is rotatable relative to the second stage movement member 114 as the rotation shaft 1161 is driven.

Additionally and optionally, in the press-fit device according to the embodiments of the present disclosure, the ram movement member 300 includes a three-piece rail cylinder, which is capable of limiting the position of the ram 200 in three positions in the first direction, respectively.

With the above technical solution, the ram movement member 300 includes a three-piece rail cylinder, which can limit the ram 200 in the three positions, such that the press-fit device can have two pressuring modes: a debug mode and a mass production mode, with which both point position can be accurately debugged and the requirement of the rapid mass production is met correspondingly. Additionally, with the three-piece rail cylinder, it can be ensured that the pressure applied on the substrate by the ram 200 is stable, thereby improving the stability of the operation, and avoiding the scrap of the substrate due to the instability of the pressure applied by the ram 200 in the related art.

The controller includes a gas pressure regulating valve 310, which is configured to regulate a pressure of the three-piece rail cylinder to control an operating state of the three-piece rail cylinder. With the above technical solution, the air pressure regulating valve 310 can control the pressure of the three-piece rail cylinder, and can further control the three-piece rail cylinder to be raised up or fall down. Also, the air pressure regulating valve 310 can control the pressure of the three-piece rail cylinder such that the pressure applied on the substrate by the ram 200 is controlled.

Specifically, an operation flow of the press-fit device in the debug mode is as follows.

When a substrate to be tested (i.e., a panel) is arranged on a stage 100 and a ram 200 is located at a first position farthest away from the substrate stage 100, a flexible printed circuit board (i.e., a first plate) is fixed by the ram 200 under the ram 200, and then the ram 200 is fall down such that the ram 200 is located at a second position at a predetermined distance (0.2 mm to 0.5 mm) over the substrate stage 100, a focal length and a position of the CCD camera is adjusted such that the CCD camera can clearly capture marking points located in left and right sides of the substrate to be tested and an alignment mark on the flexible printed circuit board under the ram 200; a position of the ram 200 in left and right directions and a position and a rotation direction of the substrate stage 100 are adjusted, such that an alignment mark of the substrate to be tested is coincident with an alignment mark on the flexible printed circuit board, and the ram 200 and the adjustment micrometer are locked after the adjustment; the ram 200 is fall down again, the ram 200 continues to press down such the flexible printed circuit board is immediately adjacent the panel, where the pressure can be adjusted through the gas pressure regulating valve; and a touch detection is started after it is observed through a display that the alignment of the press-fit device is normal.

After the press-fit device has completed the operation in the debug mode, then the press-fit device would perform an operation in the mass production mode. Compared with the operation in the debug mode, in the mass production mode, the pick and pace operations of the printed circuit board is the same as those in the debug mode, excepting that having no step for performing an alignment operation in case that the ram 200 is fall down to the second position.

An operation flow of the press-fit device in the mass production mode is as follows.

A mode switch button is pressed, when a substrate to be tested is arranged on the substrate stage 100 and the ram 200 is located at the first position farthest away from the substrate stage 100, a flexible printed circuit board is fixed by the ram 200 under the ram 200, and then the ram 200 is fall down such that the ram 200 is pressed down to a third position and is immediately adjacent the panel, i.e., a contact detection is started.

Additionally, in the press-fit device according to embodiments of the present disclosure, as shown in FIGS. 1-3, a substrate positioning member for positioning the substrate is provided on the carrier surface of the substrate stage 100.

Optionally, as shown in FIGS. 1-3, the substrate positioning member includes: a first positioning baffle 101, which is configured to position the substrate in the second direction D2 parallel to the carrier surface of the substrate stage 100; and a second positioning baffle 102, which is configured to position the substrate in the third direction D3 perpendicular to the first direction D1 and the second direction D2.

With the above technical solution, the substrate to be tested can be positioned in the front, rear, left or right directions by the first positioning baffle and the second positioning baffle.

It should be noted that, the substrate stage position adjusting member may directly adjust the position of the substrate stage 100, or may adjust the position of the substrate to be tested by moving the substrate positioning member in the second direction or the third direction, or rotating the plane in which the carrier surface of the substrate stage 100 is located.

Optionally, in the embodiments of the present disclosure, the carrier surface of the substrate stage 100 is arranged obliquely and has a predetermined inclination angle with respect to the horizontal plane, as shown in FIGS. 1-3.

With the above technical solution, the substrate stage 100 is arranged obliquely, for example, the substrate stage 100 is designed to have an inclination angle of 20°, which is advantageous that the substrate to be tested slides down and is positioned due to the gravity during positioning of the substrate to be tested.

Additionally and optionally, in the embodiments of the present disclosure, a vent hole 104 for reducing a pressure between the substrate and the carrier surface of the substrate stage 100 is provided in the carrier surface of the substrate stage 100, as shown in FIGS. 1-3.

With the technical solution, since the substrate to be tested is immediately adjacent the vent hole 104 in the substrate stage 100, the pressure is reduced when a film is taken; therefore the film is taken conveniently.

Additionally and optionally, in the embodiments of the present disclosure, as shown in FIGS. 1-3, the press-fit device further includes an ion pump 600, which is arranged above the substrate stage 100 and configured to blow a surface of the substrate and perform a dust removal and de-electrostatic process on the surface of the substrate, through which a test error rate is reduced.

Additionally and optionally, in the embodiments of the present disclosure, as shown in FIGS. 1-3, the substrate stage 100 has two substrate placement areas for placing the substrates, there are two rams 200, and one ram 200 is provided at each of the substrate placement areas.

Additionally, there may be two image acquisition members 501; and one of the two image acquisition members 501 is arranged at each of the substrate placement areas, respectively.

With the above technical solution, the press-fit device can test two substrates to be tested simultaneously, thereby reducing production operation costs, saving time and improving efficiency.

Furthermore, in the above technical solution, each ram 200 can be individually set, and performs operations separately. Similarly, each image acquisition member 501 can be also individually set, and performs operations separately, and two CCD cameras can be arranged in the image acquisition member 501, such that not only one substrate to be tested can be aligned using the two CCD cameras simultaneously, but also two substrates to be tested are aligned using the two CCD cameras respectively.

Specifically, there may be four image acquisition members 501, two CCD cameras are used to align one substrate to be tested, in this case, the left and right registration marks of each substrate to be tested can be seen through each CCD camera, the alignment of the substrates to be tested in the left and right can be displayed respectively in the left and right sides of the camera display 502, such that the alignment of two substrates to be tested can be monitored in real time, and the misjudgment of the alignment can be avoided.

It should be noted that, in the press-fit device, the substrate stage 100 has multiple substrate placement areas for placing the substrates, there are multiple rams 200, and one ram 200 is provided at each of the substrate placement areas. With the above technical solution, multiple touch panels can be tested simultaneously, and multiple substrates (for example, 3 to 8 sheets) to be tested instead of the two substrates to be tested can be arranged on the substrate positioning member, and there may be multiple rams 200 (for example, 3-8) instead of two rams 200. For a procedure which may cost long time during the test, the operation time is saved and the efficiency is improved.

It should be also noted that, when at least two substrate placement areas for placing the substrates are provided on the substrate stage 100, at least two substrate positioning members are provided correspondingly, the substrate stage position adjusting member may adjust the position of each of the substrates to be tested in each substrate placement area by moving the substrate positioning member in the second direction or the third direction, or rotating the plane in which the carrier surface of the substrate stage 100 is located. That is to say, as shown in FIGS. 1-3, there may be two first positioning baffles 101 and two second positioning baffles 102 in the substrate positioning member located in left and right instead of a single first positioning baffle 101 and a single second positioning baffle 102, which are individually adjusted by a separate adjusting micrometer.

Additionally and optionally, it should be also noted that, in the press-fit device according to the embodiments of the present disclosure, the substrate positioning member is detachably provided on the substrate stage 100, and the ram 200 is detachably provided on the ram position adjusting member 301. In this case, when a large-sized substrate to be tested is tested, what is only required is replacing the substrate positioning member and the ram 200.

In optional embodiments provided by the present disclosure, an operation flow is performed in a follow manner described hereinafter when the press-fit device tests two substrates to be tested simultaneously.

1) An operation flow of the press-fit device in the debug mode is as follows during dual products are tested:

When a ram 200 is located at a first position farthest away from the substrate stage 100, a flexible printed circuit board is fixed under the ram 200, two substrates to be tested (i.e., panel) are provided on the substrate stage 100, both of the two panel need to be immediately adjacent the first positioning baffle 101 and the second positioning baffle 102 on the substrate stage 100, a down/up button of the ram 200 is pressed down, and then the ram 200 is fall down such that the ram 200 is located at the second position at a predetermined distance (0.2 mm to 0.5 mm) over the substrate to be tested, a focal length and a position of two CCD cameras is adjusted such that the two CCD cameras can clearly capture marking points located in left and right sides of the left panel and an alignment mark on the flexible printed circuit board on the ram 200; a position of the ram 200 in left and right directions and a rotation direction of the substrate stage 100 are adjusted, such that an alignment mark of the panel is coincident with an alignment mark on the flexible printed circuit board, and the left ram position adjusting member 301 and the substrate stage 100 are locked after the adjustment; the two CCD cameras are moved above the left and right alignment marks of the right panel, an alignment mark of the right panel is adjusted with reference to the adjustment method for the left panel, and the right ram position adjusting member 301 is locked after the adjustment; and the down/up button of the ram 200 is pressed down again, the ram 200 continues to press down such that the flexible printed circuit board is immediately adjacent the panel, where the pressure can be adjusted through the gas pressure regulating valve; and a touch detection is started after it is observed through the display that the alignment of the press-fit device is normal.

2) An operation flow of the press-fit device in the mass production mode is as follows during dual products are tested:

A mode switch button is pressed, when a substrate to be tested is arranged on the substrate stage 100 and the ram 200 is located at the first position farthest away from the substrate stage 100, a flexible printed circuit board is fixed by the ram 200 under the ram 200, and then the ram 200 is fall down such that the ram 200 is pressed down to the third position and is immediately adjacent the panel, i.e., a contact detection is started.

Additionally, the embodiments of the present disclosure further provide a touch panel surface sensor detection device, which includes the press-fit device described above and a stent 500, as shown in FIG. 2. The press-fit device is arranged on the stent 500. With the press-fit device, the flexible printed circuit board can be arranged on the ram 200, and the touch panel to be tested is arranged on the substrate stage 100, such that the flexible printed circuit board is pressed on the touch panel to be tested and touch detection is performed.

Those described above are merely optional embodiments of the present disclosure. It should be noted that, for the skilled in the art, improvements and replacements may also be made without departing from the technical principle of the present disclosure. Those improvements and replacements should also be included in the scope of protection of the present disclosure.

1. A press-fit device for pressing a first plate on a substrate, wherein the press-fit device comprises:
a substrate stage for placing the substrate;
a ram, arranged on the substrate stage and configured to secure the first plate;
a ram movement member, connected with the ram and configured to control the ram to be pressed down or raised up in a first direction perpendicular to the substrate stage;
a controller, configured to control an operating state of the ram movement member; and
an alignment member, configured to control alignment of the ram and the substrate stage;
wherein the alignment member is connected to the ram and the substrate stage.

2. The press-fit device according to claim 1, wherein the alignment member comprises: a ram position adjusting member, a substrate stage position adjusting member and an alignment controlling member;
wherein the ram position adjusting member is configured to control the ram to be moved in a plane parallel to a carrier surface of the substrate stage, to adjust a position of the first plate on the ram;
the substrate stage position adjusting member is configured to control the substrate stage to be moved in a plane in which the carrier surface of the substrate stage is located, to adjust a position of the substrate on the substrate stage; and
the alignment controlling member, configured to obtain current position information of the first plate on the ram and the substrate on the substrate stage, and control operating states of the ram position adjusting member and the substrate stage position adjusting member according to the current position information, to align the first plate with the substrate.

3. The press-fit device according to claim 2, wherein the alignment controlling member comprises an image acquisition member and a control member;
wherein the image acquisition member is arranged on the substrate stage, configured to acquire image information of the first plate on the ram and the substrate on the substrate stage to obtain the current position information of the first plate on the ram and the substrate on the substrate stage; and
the control member is configured to control the operating states of the ram position adjusting member and the substrate stage position adjusting member according to the image information acquired by the image acquisition member.

4. The press-fit device according to claim 3, wherein the alignment controlling member further comprises an image acquisition member moving component, configured to move the image acquisition member.

5. The press-fit device according to claim 2, wherein the ram position adjusting member comprises:
a ram moving member, configured to translate the ram in a second direction parallel to the carrier surface of the substrate stage.

6. The press-fit device according to claim 2, wherein the substrate stage position adjusting member comprises:
a first stage moving member, configured to translate the substrate stage in a second direction parallel to the carrier surface of the substrate stage;
a second stage moving member, configured to translate the substrate stage in a third direction perpendicular to the first direction and the second direction; and
a third stage moving member, configured to rotate the substrate stage in the plane in which the carrier surface of the substrate stage is located.

7. The press-fit device according to claim 1, wherein the ram movement member comprises:
a three-piece rail cylinder, capable of limiting the position of the ram in three positions in the first direction, respectively.

8. The press-fit device according to claim 7, wherein the controller comprises a gas pressure regulating valve, which is configured to regulate a cylinder pressure of the three-piece rail cylinder to control an operating state of the three-piece rail cylinder.

9. The press-fit device according to claim 1, wherein a substrate positioning member for positioning the substrate is provided on the carrier surface of the substrate stage.

10. The press-fit device according to claim 9, wherein the substrate positioning member comprises:
a first positioning baffle, configured to position the substrate in a second direction parallel to a carrier surface of the substrate stage; and a second positioning baffle, configured to position the substrate in a third direction perpendicular to the first direction and the second direction.

11. The press-fit device according to claim 10, wherein the carrier surface of the substrate stage is inclined with respect to a horizontal plane.

12. The press-fit device according to claim 1, wherein a vent hole for reducing a pressure between the substrate and a carrier surface of the substrate stage is provided in the carrier surface of the substrate stage.

13. The press-fit device according to claim 1, further comprising an ion pump;
wherein the ion pump is arranged on the substrate stage and configured to blow a surface of the substrate and perform a dust removal and de-electrostatic process on the surface of the substrate.

14. The press-fit device according to claim 1, wherein the substrate stage has at least two substrate placement areas, there are two rams, and one of the two rams is provided at each of the substrate placement areas.

15. A touch panel surface sensor detection device, comprising the press-fit device according to claim 1.
